(19) United States
(12) Patent Application Publication
(10) Pub. No.: US 2020/0243759 A1
(43) Pub. Date: Jul. 30, 2020

(54) METHOD OF ETCHING

(71) Applicant: Tokyo Electron Limited, Tokyo (JP)

(72) Inventors: Takuya KUBO, Minato-ku, Tokyo (JP); Song yun KANG, Minato-ku, Tokyo (JP)

(73) Assignee: Tokyo Electron Limited, Tokyo (JP)

(21) Appl. No.: 16/756,835

(22) PCT Filed: Oct. 15, 2018
(86) PCT No.: PCT/JP2018/038367

§ 371 Date: Apr. 16, 2020

(30) Foreign Application Priority Data
Oct. 27, 2017 (JP) 2017-207991

(51) Int. Cl. H01L 43/12; H01L 43/02; H01L 21/67; H01L 43/10; H01F 10/32; G11C 11/16; H01F 41/34

(52) U.S. Cl. CPC H01L 43/12; H01L 43/02; H01L 21/67069; H01F 41/34; H01F 10/3254; G11C 11/161; H01L 43/10

(57) ABSTRACT

In a method of etching according to one embodiment, a multilayer film having a magnetic tunnel junction layer is etched. In the method of etching, a plasma processing apparatus is used. A chamber body of the plasma processing apparatus provides an internal space. In the method of etching, a workpiece is accommodated in the internal space. Next, the multilayer film is etched by plasma of a first gas generated in the internal space. The first gas includes carbon and a rare gas and does not include hydrogen. Next, the multilayer film is further etched by plasma of a second gas generated in the internal space. The second gas includes oxygen and a rare gas and does not include carbon and hydrogen.

### TECHNICAL FIELD

Embodiments of the present disclosure relate to a method of etching a multilayer film of a workpiece, which is executed in manufacture of a magnetoresistance effect device.

### BACKGROUND ART

A magnetoresistance effect device which includes a magnetic tunnel junction (MTJ) layer is used in a device such as an MRAM (Magnetoresistive Random Access Memory), for example.

In manufacture of the magnetoresistance effect device, etching of a multilayer film is performed. In etching which is executed in the manufacture of the magnetoresistance effect device, plasma of a hydrocarbon gas and an inert gas is generated in an internal space of a chamber body of a plasma processing apparatus, and the multilayer film is irradiated with ions and radicals from the plasma. As a result, the multilayer film is etched. Such etching is described in Patent Literature 1. In the etching described in Patent Literature 1, a nitrogen gas and a rare gas are used as the inert gas.

### CITATION LIST

### Patent Literature

[Patent Literature 1] Japanese Patent Application Laid-Open Publication No. 2011-14881

### SUMMARY OF INVENTION

### Technical Problem

When the multilayer film is etched by generating plasma of a hydrocarbon gas, a deposit is formed on a workpiece which includes the multilayer film The amount of the deposit should be reduced. As a method of etching which makes it possible to reduce the amount of deposit, a method of etching is conceivable in which etching the multilayer film by plasma of a hydrocarbon gas and a rare gas generated in an internal space of a plasma processing apparatus, and removing a deposit by plasma of a hydrogen gas and a nitrogen gas generated in the internal space are alternately executed. However, the method of etching requires further improvement in suppression of deterioration of the magnetic characteristics of the magnetoresistance effect device.

### Solution to Problem

In one aspect, a method of etching a multilayer film of a workpiece, which is executed in manufacture of a magnetoresistance effect device, is provided. The multilayer film has a magnetic tunnel junction layer, and the magnetic tunnel junction layer includes a first magnetic layer, a second magnetic layer, and a tunnel barrier layer provided between the first magnetic layer and the second magnetic layer. In the method of etching, a plasma processing apparatus is used. The plasma processing apparatus includes a chamber body. The chamber body provides an internal space. The method of etching includes (i) accommodating a workpiece in the internal space, (ii) etching the multilayer film by plasma of a first gas generated in the internal space, in which the first gas includes carbon and a rare gas and does not include hydrogen; and (iii) further etching the multilayer film by plasma of a second gas generated in the internal space, in which the second gas includes oxygen and a rare gas, and does not include carbon and hydrogen.

When the multilayer film is etched by plasma of a gas containing hydrogen, the magnetic characteristics of the magnetoresistance effect device deteriorate. It is presumed that this is because hydrogen ions and/or radicals deteriorate the multilayer film of the magnetoresistance effect device. In the method of etching according to the one aspect, since both the first gas and the second gas which are used for etching of the multilayer film do not include hydrogen, deterioration of the magnetic characteristics of the magnetoresistance effect device due to the etching of the multilayer film is suppressed. Further, in the method of etching according to the one aspect, a deposit including carbon which is derived from the first gas is formed on the workpiece. The amount of the deposit is reduced by the ions and/or radicals of oxygen contained in the second gas. In the second gas, since the oxygen gas is diluted with the rare gas, excessive oxidation of the multilayer film is suppressed.

In one embodiment, the first gas may further contain oxygen. In an embodiment, the first gas may include a carbon monoxide gas or a carbon dioxide gas.

In one embodiment, the etching the multilayer film by plasma of a first gas and the further etching the multilayer film by plasma of a second gas may be alternately repeated.

In one embodiment, the method of etching may further include generating plasma of a third gas in the internal space before accommodating the workpiece in the internal space. The third gas may include a gas containing carbon and a rare gas. When the plasma of the third gas is generated in the internal space, a coating containing carbon is formed on a surface defining the internal space. The ions and/or radicals of oxygen contained in the second gas are partially consumed in a reaction with carbon in the coating. According to the embodiment, the oxidation of the multilayer film is further suppressed. Therefore, according to the embodiment, a decrease in the etching rate of the multilayer film is suppressed.

In one embodiment, the third gas may include a gas containing hydrocarbon, as the gas containing carbon.

In one embodiment, the method of etching may further include executing cleaning of a surface defining the internal space after the multilayer film is etched by executing etching the multilayer film by plasma of a first gas and the further etching the multilayer film by plasma of a second gas. According to the embodiment, after the etching of the multilayer film ML of the workpiece W is executed, the coating described above may be removed by the cleaning.

In one embodiment, the method of etching may further include transferring the workpiece out from the internal space after the multilayer film is etched and before the executing cleaning. According to the embodiment, after the multilayer film is etched and the workpiece is transferred out from the internal space, the coating is removed by the cleaning. Then, the coating described above is formed again before another workpiece is transferred in the internal space. Thereafter, etching of the multilayer film of another workpiece is executed. According to the embodiment, the multilayer films of two or more workpieces may be sequentially etched under the same environment.

In one embodiment, each of the first magnetic layer and the second magnetic layer may be a CoFeB layer, and the tunnel barrier layer may be an MgO layer.

### Advantageous Effects of Invention

As described above, a method for etching is provided in which it is possible to suppress deterioration of the magnetic characteristics of the magnetoresistance effect device.

### BRIEF DESCRIPTION OF DRAWINGS

FIG. 1 is a flowchart showing a method of etching according to an embodiment.

FIG. 2 is a sectional view showing a part of a workpiece of an example in an enlarged manner.

FIG. 3 is a diagram schematically showing a plasma processing apparatus that can be used for execution of the method of etching shown in FIG. 1.

FIG. 4A is a diagram for describing plasma generated in steps ST1 and ST2, and FIG. 4B is a diagram showing the state of the workpiece in steps ST1 and ST2.

FIG. 5 is a diagram showing the state of the workpiece at the time of the end of the method of etching shown in FIG. 1.

FIG. 6 is a graph showing the results of a third experiment.

### DESCRIPTION OF EMBODIMENTS

Hereinafter, various embodiments will be described in detail with reference to the drawings. In the drawings, identical or corresponding portions are denoted by the same reference symbols.

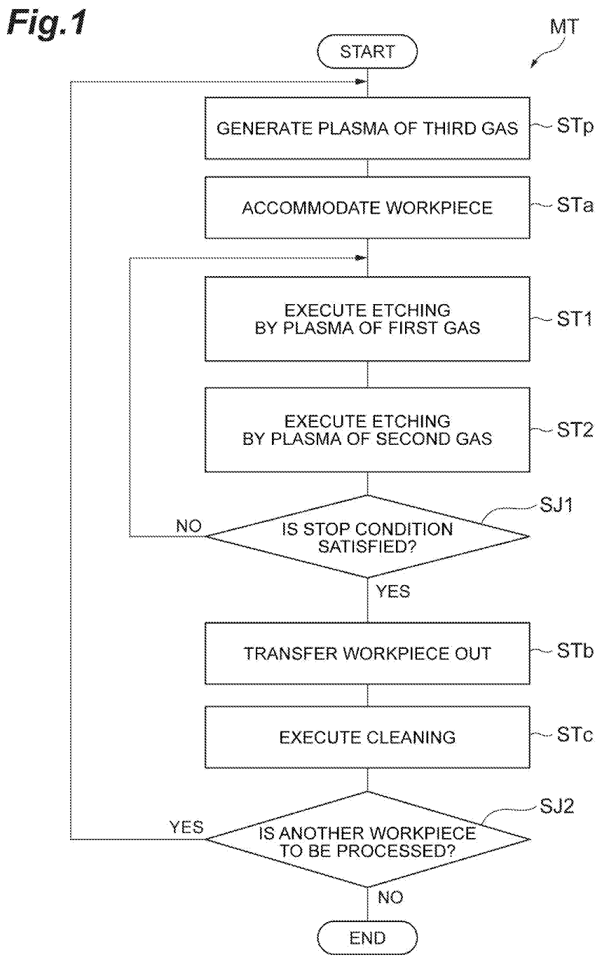

FIG. 1 is a flowchart showing a method of etching according to one embodiment. The method of etching (hereinafter, referred to as a “method MT”) shown in FIG. 1 is a method of etching a multilayer film of a workpiece and is executed in manufacture of a magnetoresistance effect device.

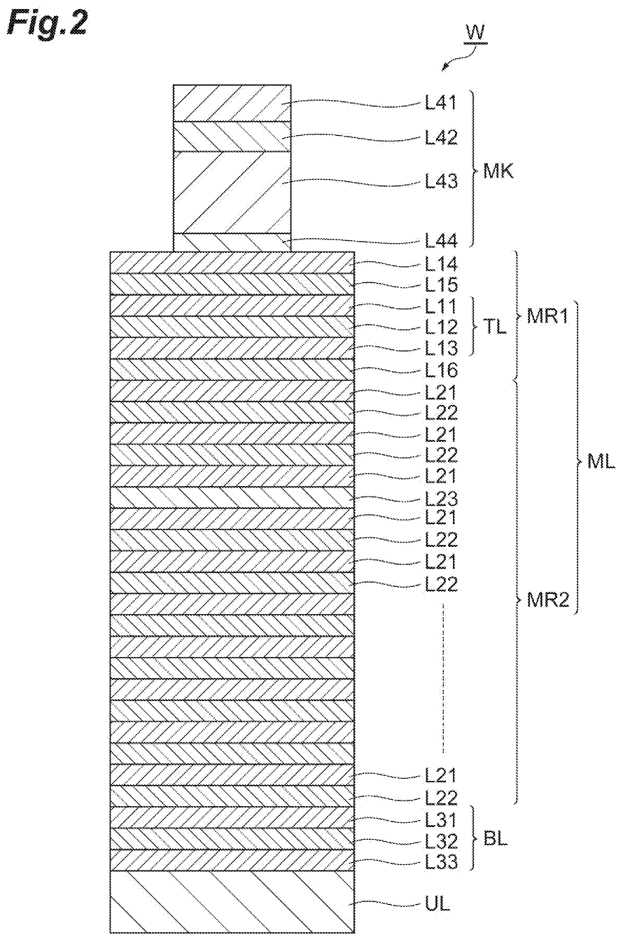

FIG. 2 is a sectional view showing a part of a multilayer film of a workpiece of an example in an enlarged manner. The method MT may be executed for etching of a multilayer film ML of a workpiece W shown in FIG. 2. As shown in FIG. 2, the workpiece W has the multilayer film ML. The multilayer film ML includes at least a magnetic tunnel junction layer TL.

The magnetic tunnel junction layer TL includes a first magnetic layer L11, a tunnel barrier layer L12, and a second magnetic layer L13. The tunnel barrier layer L12 is provided between the first magnetic layer L11 and the second magnetic layer L13. Each of the first magnetic layer L11 and the second magnetic layer L13 is, for example, a CoFeB layer. The tunnel barrier layer L12 is an insulating layer formed of a metal oxide. The tunnel barrier layer L12 is, for example, a magnesium oxide layer (MgO layer).

The multilayer film ML may have a first multilayer region MR1 and a second multilayer region MR2. The first multilayer region MR1 includes the magnetic tunnel junction layer TL described above. The first multilayer region MR1 may further include a cap layer L14, an upper layer L15, and a lower layer L16. The magnetic tunnel junction layer TL is provided on the lower layer L16. The upper layer L15 is provided on the magnetic tunnel junction layer TL. The cap layer L14 is provided on the upper layer L15. The upper layer L15 and the lower layer L16 are made of, for example, tungsten (W). The cap layer L14 is made of, for example, tantalum (Ta).

The first multilayer region MR1 is provided on the second multilayer region MR2. The second multilayer region MR2 may include a metal multilayer film forming a pinning layer in the magnetoresistance effect device. The second multilayer region MR2 includes a plurality of cobalt layers L21 and a plurality of platinum layers L22. The plurality of cobalt layers L21 and the plurality of platinum layers L22 are alternately laminated. The multilayer film ML2 may further include a ruthenium (Ru) layer L23. The ruthenium layer L23 is interposed between any two layers in the alternate lamination of the plurality of cobalt layers L21 and the plurality of platinum layers L22.

The workpiece W may further include a lower electrode layer BL and a underlying layer UL. The underlying layer UL is made of, for example, silicon oxide. The lower electrode layer BL is provided on the underlying layer UL. The second multilayer region MR2 is provided on the lower electrode layer BL. The lower electrode layer BL may include a first layer L31, a second layer L32, and a third layer L33. The third layer L33 is a Ta layer and is provided on the underlying layer UL. The second layer L32 is a Ru layer and is provided on the third layer L33. The first layer L31 is a Ta layer and is provided on the second layer L32.

The workpiece W further has a mask MK. The mask MK is provided on the first multilayer region MR1. Although the mask MK may be formed in a single layer, the mask is a laminated body in the example shown in FIG. 2. In the example shown in FIG. 2, the mask MK includes layers L41 to L44. The layer L41 is formed of silicon oxide, the layer L42 is made of silicon nitride, the layer L43 is made of titanium nitride (TiN), and the layer L44 is made of ruthenium.

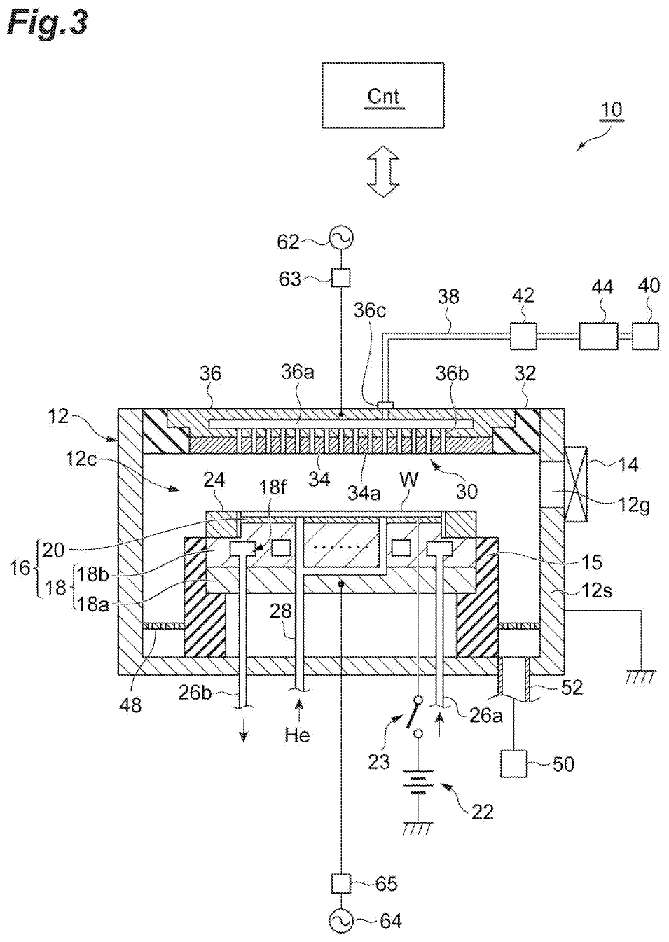

Hereinafter, the method MT will be described by taking, as an example, a case where the method is applied to the workpiece W shown in FIG. 2. In the method MT, a plasma processing apparatus is used. FIG. 3 is a diagram schematically showing a plasma processing apparatus that can be used for the execution of the method of etching shown in FIG. 1. In FIG. 3, the structure in the longitudinal section of the plasma processing apparatus is schematically shown. A plasma processing apparatus 10 shown in FIG. 3 is a capacitively-coupled plasma processing apparatus.

The plasma processing apparatus 10 includes a chamber body 12. The chamber body 12 has a substantially cylindrical shape. The chamber body 12 provides an inner space thereof as an internal space 12c. The chamber body 12 is made of, for example, aluminum. The chamber body 12 is connected to a ground potential. A film having plasma resistance is formed on the inner wall surface of the chamber body 12, that is, a wall surface defining the internal space 12c. The film may be a film formed by anodization, or a film made of ceramics, such as a film made of yttrium oxide. An opening 12g is formed in a side wall 12s of the chamber body 12. The workpiece W passes through the opening 12g when it is transferred in and transferred out from the internal space 12c. The opening 12g can be opened and closed by a gate valve 14. The gate valve 14 is provided along the side wall 12s.

A supporting part 15 is provided in the internal space 12c. The supporting part 15 extends upward from a bottom portion of the chamber body 12. The supporting part 15 has a substantially cylindrical shape. The supporting part 15 is made of an insulating material such as quartz. A stage 16 is further provided in the internal space 12c. The stage 16 is supported by the supporting part 15. The stage 16 is configured to support the workpiece W mounted thereon. The workpiece W may have a disk shape like a wafer. The stage 16 includes a lower electrode 18 and an electrostatic chuck 20.

The lower electrode 18 includes a first plate 18a and a second plate 18b. The first plate 18a and the second plate 18b are made of metal such as aluminum, for example. Each of the first plate 18a and the second plate 18b has a substantially disk shape. The second plate 18b is provided on the first plate 18a and electrically connected to the first plate 18a.

The electrostatic chuck 20 is provided on the second plate 18b. The electrostatic chuck 20 includes an insulating layer and an electrode built in the insulating layer. A direct-current power source 22 is electrically connected to the electrode of the electrostatic chuck 20 through a switch 23. If a direct-current voltage from the direct-current power source 22 is applied to the electrode of the electrostatic chuck 20, an electrostatic attraction force is generated between the electrostatic chuck 20 and the workpiece W. Due to the generated electrostatic attraction force, the workpiece W is attracted to the electrostatic chuck 20 and held by the electrostatic chuck 20.

A focus ring 24 is disposed on a peripheral edge portion of the second plate 18b to surround the edge of the workpiece W and the electrostatic chuck 20. The focus ring 24 is disposed in order to improve the uniformity of plasma processing. The focus ring 24 is made of a material which is appropriately selected according to the plasma processing, and is made of, for example, quartz.

A flow path 18f is disposed in the interior of the second plate 18b. A refrigerant is supplied to the flow path 18f from a chiller unit provided outside the chamber body 12 through a pipe 26a. The refrigerant supplied to the flow path 18f is returned to the chiller unit through a pipe 26b. The refrigerant is circulated between the chiller unit and the flow path 18f. The temperature of the workpiece W supported by the electrostatic chuck 20 is controlled by controlling the temperature of the refrigerant by the chiller unit.

The plasma processing apparatus 10 is provided with a gas supply line 28. The gas supply line 28 supplies a heat transfer gas, for example, a He gas, from a heat transfer gas supply mechanism to the gap between the upper surface of the electrostatic chuck 20 and the back surface of the workpiece W.

The plasma processing apparatus 10 further includes an upper electrode 30. The upper electrode 30 is disposed above the stage 16 and is disposed substantially parallel to the lower electrode 18. The upper electrode 30 closes an upper opening of the chamber body 12 together with a member 32. The member 32 has insulation properties. The upper electrode 30 is supported on the upper portion of the chamber body 12 through the member 32.

The upper electrode 30 includes a ceiling plate 34 and a support 36. The ceiling plate 34 faces the internal space 12c. A plurality of gas discharging holes 34a are disposed in the ceiling plate 34. The ceiling plate 34 is made of, for example, silicon. However, there is no limitation thereto. Alternatively, the ceiling plate 34 may have a structure in which a plasma-resistant film is provided on the surface of a base material made of aluminum. The film may be a film made by anodization, or a film made of ceramics, such as a film made of yttrium oxide.

The support 36 is configured to detachably support the ceiling plate 34. The support 36 can be formed of a conductive material such as aluminum. A gas diffusion chamber 36a is disposed in the interior of the support 36. A plurality of gas holes 36b extend downward from the gas diffusion chamber 36a. The plurality of gas holes 36b communicate with the plurality of gas discharging holes 34a, respectively. A gas introduction port 36c for leading a gas to the gas diffusion chamber 36a is formed in the support 36. A gas supply pipe 38 is connected to the gas introduction port 36c.

A gas source group 40 is connected to the gas supply pipe 38 through a valve group 42 and a flow rate controller group 44. The gas source group 40 has a plurality of gas sources for a first gas, a second gas, a third gas, and a cleaning gas. The first gas, the second gas, the third gas, and the cleaning gas will be described later.

The valve group 42 includes a plurality of valves, and the flow rate controller group 44 includes a plurality of flow rate controllers such as mass flow controllers. Each of the plurality of gas sources in the gas source group 40 is connected to the gas supply pipe 38 through a corresponding valve of the valve group 42 and a corresponding flow rate controller of the flow rate controller group 44. The plasma processing apparatus 10 can supply gases from one or more gas sources selected from the plurality of gas sources of the gas source group 40 to the internal space 12c at individually adjusted flow rates.

A baffle plate 48 is disposed between the supporting part 15 and the side wall 12s of the chamber body 12. The baffle plate 48 may be made, for example, by coating a base material made of aluminum with ceramics such as yttrium oxide. A large number of through-holes are formed in the baffle plate 48. An exhaust pipe 52 is connected to the bottom portion of the chamber body 12 below the baffle plate 48. An exhaust device 50 is connected to the exhaust pipe 52. The exhaust device 50 has a pressure controller such as an automatic pressure control valve, and a vacuum pump such as a turbo molecular pump, and can reduce the pressure in the internal space 12c.

The plasma processing apparatus 10 further includes a first radio frequency power source 62. The first radio frequency power source 62 is a power source that generates a first radio frequency wave for plasma generation. The frequency of the first radio frequency wave is a frequency in the range of 27 MHz to 100 MHz, and is, for example, 60 MHz. The first radio frequency power source 62 is connected to the upper electrode 30 through a matching device 63. The matching device 63 has a circuit for matching the output impedance of the first radio frequency power source 62 with the input impedance on the load side (the upper electrode 30 side). The first radio frequency power source 62 may be connected to the lower electrode 18 through the matching device 63. In a case where the first radio frequency power source 62 is connected to the lower electrode 18, the upper electrode 30 is connected to a ground potential.

The plasma processing apparatus 10 further includes a second radio frequency power source 64. The second radio frequency power source 64 is a power source that generates a second radio frequency wave for bias for drawing ions into the workpiece W. The frequency of the second radio frequency wave is lower than the frequency of the first radio frequency wave. The frequency of the second radio frequency wave is a frequency in the range of 400 kHz to 13.56 MHz, and is, for example, 400 kHz. The second radio frequency power source 64 is connected to the lower electrode 18 through a matching device 65. The matching device 65 has a circuit for matching the output impedance of the second radio frequency power source 64 with the input impedance on the load side (the lower electrode 18 side).

In one embodiment, the plasma processing apparatus 10 may further include a controller Cnt. The controller Cnt is a computer which includes a processor, a storage device, an input device, a display device, and the like, and controls each part of the plasma processing apparatus 10. Specifically, the controller Cnt executes a control program stored in the storage device, and controls each part of the plasma processing apparatus 10, based on recipe data stored in the storage device. Accordingly, the plasma processing apparatus 10 is made to execute a process specified by the recipe data. For example, the controller Cnt controls each part of the plasma processing apparatus 10, based on recipe data for the method MT.

When the plasma processing is executed by using the plasma processing apparatus 10, the gas from the selected gas source among the plurality of gas sources of the gas source group 40 is supplied into the internal space 12c. The internal space 12c is depressurized by the exhaust device 50. Then, the gas supplied to the internal space 12c is excited by a radio frequency electric field generated by the radio frequency from the first radio frequency power source 62. As a result, plasma is generated in the internal space 12c. The second radio frequency wave is supplied to the lower electrode 18. As a result, ions in the plasma are accelerated toward the workpiece W. The workpiece W is irradiated with the accelerated ions and/or radicals, whereby the workpiece is etched.

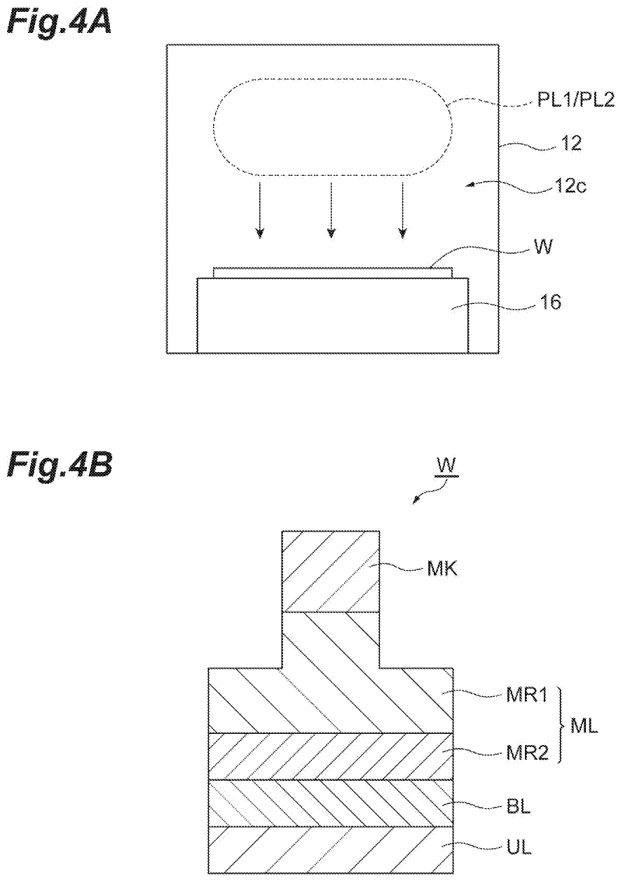

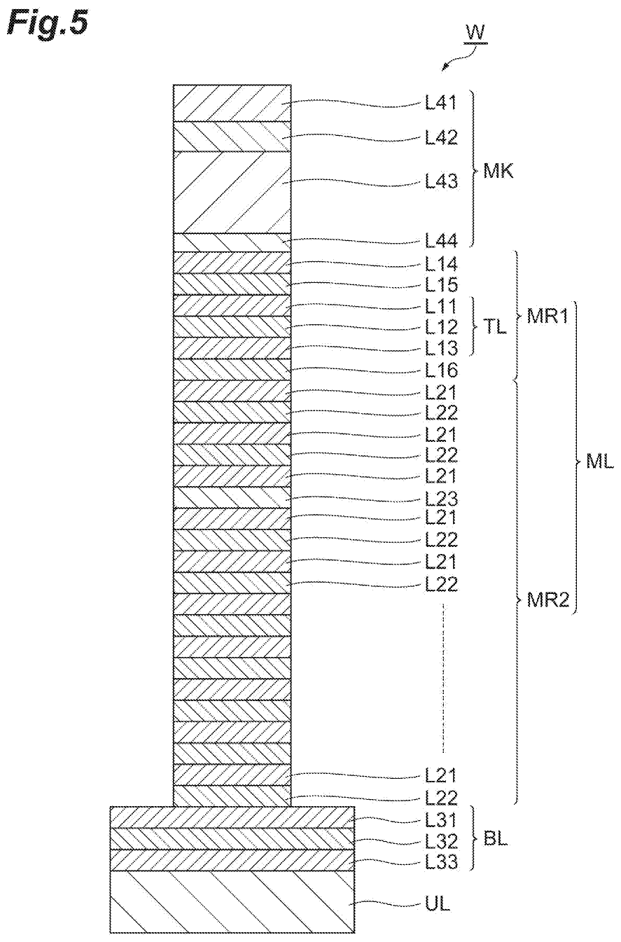

Hereinafter, the method MT will be described in detail with reference to FIGS. 4A, 4B, and 5 together with FIG. 1. FIG. 4A is a diagram for describing the plasma generated in steps ST1 and ST2, and FIG. 4B is a diagram showing the state of the workpiece in steps ST1 and ST2. FIG. 5 is a diagram showing the state of the workpiece at the time of the end of the method of etching shown in FIG. 1. In the following description, the method MT will be described by using, as an example, a case where the method MT is applied to the workpiece W shown in FIG. 2 by using the plasma processing apparatus 10.

As shown in FIG. 1, the method MT includes step STa, step ST1, and step ST2. In an embodiment, the method MT further includes step STp. In another embodiment, the method MT further includes step STb and step STc.

In step STa, the workpiece W is accommodated in the internal space 12c. The workpiece W is placed on the electrostatic chuck 20 of the stage 16 and held by the electrostatic chuck 20.

In one embodiment, step STp is executed before the execution of step STa. In step STp, plasma PL3 of a third gas is generated in the internal space 12c. The third gas contains a gas containing carbon and a rare gas. The gas containing carbon includes, for example, hydrocarbon such as methane (CH₄), carbon oxide such as carbon monoxide (CO), or fluorocarbon such as C₄F₆. The rare gas may be any rare gas and is, for example, an argon (Ar) gas. In step STp, the third gas is supplied to the internal space 12c in a state where an object such as a dummy wafer is placed on the electrostatic chuck 20. In step STp, the pressure in the internal space 12c is set to a specified pressure by the exhaust device 50. In step STp, the first radio frequency wave is supplied in order to generate the plasma of the third gas. In a case where the plasma of the third gas is generated in step STp, a coating is formed on the surface defining the internal space 12c, for example, the inner wall surface of the chamber body 12. The coating includes carbon contained in the third gas.

In the method MT, steps ST1 and ST2 are executed after the execution of step STa, steps ST1 and ST2. In step ST1, the multilayer film ML is etched by plasma of a first gas. The first gas is a gas which contains carbon and a rare gas and does not include hydrogen. The first gas may further include oxygen. When containing oxygen, the first gas may include a carbon monoxide gas or a carbon dioxide gas. The rare gas in the first gas may be any rare gas and is, for example, an Ar gas. In an example, the first gas includes a carbon monoxide gas and an Ar gas.

In step ST1, the first gas is supplied from the gas source group 40 to the internal space 12c. The pressure in the internal space 12c is set to a specified pressure by the exhaust device 50. The first radio frequency wave is supplied from the first radio frequency power source 62 for plasma generation. In step ST1, the first gas is excited by the radio frequency electric field based on the first radio frequency wave in the internal space 12c, and thus plasma PL1 of the first gas is generated (refer to FIG. 4A). In step ST1, the second radio frequency wave is supplied from the second radio frequency power source 64 to the lower electrode 18. The second radio frequency wave is supplied to the lower electrode 18, whereby ions (ions of carbon and rare gas atoms) in the plasma PL1 are attracted to the workpiece W, so that the workpiece W is irradiated with the ions.

In step ST1, the multilayer film ML is modified by the ions and/or radicals of carbon from the plasma PL1 such that the multilayer film ML is easily etched. Further, the ions from the plasma PL1 colliding with the multilayer film ML, whereby the multilayer film ML is etched. That is, in step ST1, the multilayer film ML is etched by ion sputtering. By execution of step ST1, the multilayer film ML is etched at the portion exposed from the mask MK. As a result, as shown in FIG. 4B, the pattern of the mask MK is transferred to the multilayer film ML. In step ST1, there is a case where a deposit containing carbon is formed on the surface of the workpiece W.

In subsequent step ST2, the multilayer film ML is further etched by plasma of a second gas. The second gas includes oxygen and a rare gas and does not include carbon and hydrogen. The rare gas may be any rare gas and is, for example, an Ar gas. The second gas includes an oxygen gas and an Ar gas, as an example.

In step ST2, the second gas is supplied from the gas source group 40 to the internal space 12c. The pressure in the internal space 12c is set to a specified pressure by the exhaust device 50. Further, in step ST2, the first radio frequency wave is supplied from the first radio frequency power source 62 for plasma generation. In step ST2, the second gas is excited by the radio frequency electric field based on the first radio frequency wave in the internal space 12c, and thus plasma PL2 of the second gas is generated (refer to FIG. 4A). In step ST2, the second radio frequency wave is supplied from the second radio frequency power source 64 to the lower electrode 18. The second radio frequency wave is supplied to the lower electrode 18, whereby ions (ions of oxygen or rare gas atoms) from the plasma PL2 are attracted to the workpiece W to collide with the workpiece W. The multilayer film ML is etched by ion sputtering. In step ST2, the deposit containing carbon on the workpiece W is removed by oxygen ions and/or radicals.

In the method MT, a sequence which includes in each of steps ST1 and ST2 is executed one or more times. In a case where the sequence is executed multiple times, in step SJ1, it is determined whether or not a stop condition is satisfied. The stop condition is satisfied in a case where the number of executions of the sequence has reached a predetermined number of times. In step SJ1, when it is determined that the stop condition is not satisfied, the sequence is executed again. Step ST1 and step ST2 are alternately repeated. When it is determined that the stop condition is satisfied in step SJ1, the execution of the sequence is ended. When the execution of the sequence by a predetermined number of times is ended, the multilayer film ML is in the state shown in FIG. 5. That is, in an embodiment, the sequence is executed until the lower electrode layer BL is exposed, and thus the pillar shown in FIG. 5 is formed from the multilayer film ML.

Subsequently, in the method MT, step STb is executed. In step STb, the workpiece W is transferred out from the internal space 12c to the outside of the chamber body 12. In the method MT, step STc is executed after the execution of step STb. In step STc, cleaning of the surface defining the internal space 12c is executed.

In step STc, a cleaning gas is supplied to the internal space 12c. The cleaning gas includes an oxygen-containing gas. The oxygen-containing gas may be, for example, an oxygen gas (O₂ gas), a carbon monoxide gas, or a carbon dioxide gas. In step STc, the pressure in the internal space 12c is set to a specified pressure by the exhaust device 50. In step STc, the first radio frequency wave is supplied from the first radio frequency power source 62 for plasma generation. In step STc, the cleaning gas is excited by the radio frequency electric field based on the first radio frequency wave in the internal space 12c, and thus plasma of the cleaning gas is generated. In step STc, the coating containing carbon on the surface defining the internal space 12c, for example, the inner wall surface of the chamber body 12 is removed by active species of oxygen from the plasma of the cleaning gas. Step STc may be executed in a state where an object such as a dummy wafer is placed on the electrostatic chuck 20 and held by the electrostatic chuck 20. Alternatively, step STc may be executed in a state where an object such as a dummy wafer is not placed on the electrostatic chuck 20.

In subsequent step SJ2, it is determined whether or not another workpiece is to be processed. It is determined whether or not to etch a multilayer film of another workpiece. In a case where it is determined that another workpiece is to be processed in step SJ2, the processing from step STp is executed again, and thus the multilayer film of another workpiece is etched. In a case where it is determined that another workpiece is not to be processed in step SJ2, the method MT is ended.

When the multilayer film ML is etched by the plasma of gas containing hydrogen, the magnetic characteristics of the magnetoresistance effect device deteriorate. It is presumed that this is because hydrogen ions and/or radicals deteriorate the multilayer film ML of the magnetoresistance effect device. On the other hand, in the method MT, since both the first gas and the second gas which are used for the etching of the multilayer film ML do not include hydrogen, the deterioration of the magnetic characteristics of the magnetoresistance effect device due to the etching of the multilayer film ML is suppressed. Further, in the method MT, a deposit containing carbon which is derived from the first gas is formed on the workpiece W. The amount of the deposit is reduced by the ions and/or radicals of oxygen contained in the second gas. In the second gas, since the oxygen gas is diluted with the rare gas, excessive oxidation of the multilayer film ML is suppressed.

In an embodiment, as described above, in step STp, the plasma of the third gas is generated in the internal space 12c. When the plasma of the third gas is generated in the internal space 12c, a coating containing carbon is formed on the surface defining the internal space 12c. The ions and/or radicals of oxygen contained in the second gas are partially consumed in a reaction with carbon in the coating. According to the embodiment, the oxidation of the multilayer film ML is suppressed. A decrease in the etching rate of the multilayer film ML is suppressed.

Although various embodiments have been described above, various modification aspects can be made without being limited to the embodiments described above. For example, a plasma processing apparatus other than the capacitively-coupled plasma processing apparatus can be used for the execution of the method MT and methods according to the modification aspects. As such a plasma processing apparatus, an inductively coupled plasma processing apparatus and a plasma processing apparatus that uses surface waves such as microwaves for generation of plasma are exemplified.

The multilayer film which is etched in the method MT includes at least the magnetic tunnel junction layer TL. In other words, the sequence which includes steps ST1 and ST2 is executed in order to etch at least the magnetic tunnel junction layer TL. The regions of the multilayer film ML other than the magnetic tunnel junction layer TL may be etched by processing different from the sequence which includes steps ST1 and ST2.

The cleaning of step STc may be executed after the multilayer films ML of two or more workpieces are sequentially etched by the execution of steps STp, STa, ST1, and ST2. The workpiece other than the workpiece whose multilayer film ML is finally etched, among the two or more workpieces, is transferred out from the internal space 12c before the workpiece whose multilayer film ML is etched next is accommodated in the internal space 12c. The cleaning in step STc may be executed while the workpiece whose multilayer film ML is finally etched, among the two or more workpieces, is being disposed in the internal space 12c or after the workpiece is transferred out to the outside of the chamber body 12.

Hereinafter, various experiments performed for the evaluation of the method MT will be described. The present disclosure is not limited by the experiments described below.

(First Experiment)

In a first experiment, a plurality of experimental samples 1 (296 samples) were fabricated by etching the multilayer film of the workpiece having the structure shown in FIG. 2 by executing the sequence which includes each of steps ST1 and ST2. The plasma processing apparatus having the structure shown in FIG. 3 was used in the fabrication of the plurality of experimental samples 1. The processing conditions in the fabrication of the plurality of experimental samples 1 are shown below.

### <Processing Conditions in Fabrication of Experimental Samples 1>

Step ST1

Pressure in Internal space: 10 [mTorr] (1.333 [Pa])

Flow rate of Ar gas in first gas: 25 [sccm]

Flow rate of carbon monoxide (CO) gas in first gas: 175 [sccm]

First radio frequency wave: 60 [MHz], 200 [W]

Second radio frequency wave: 400 [kHz], 800 [W]

Processing time: 5 [seconds]

### Step ST2

Pressure in Internal space: 10 [mTorr] (1.333 [Pa])

Flow rate of Ar gas in second gas: 194 [sccm]

Flow rate of oxygen (O₂) gas in second gas: 6 [sccm]

First radio frequency wave: 60 [MHz], 200 [W]

Second radio frequency wave: 400 [kHz], 800 [W]

Processing time: 5 [seconds]

Number of executions of sequence: 35 times

Further, in the first experiment, for comparison, a plurality of comparative samples 1 (287 samples) were fabricated by etching the multilayer film of the workpiece having the structure shown in FIG. 2 by executing a sequence which includes each of a first step and a second step. The plasma processing apparatus having the structure shown in FIG. 3 was used also in the fabrication of the plurality of comparative samples 1. The processing conditions in the fabrication of the plurality of comparative samples 1 are shown below. In the first step, a methane (CH₄) gas containing hydrogen was used.

### <Processing Conditions of First and Second Steps in Fabrication of Comparative Samples 1>

### First Step

Pressure in Internal space: 10 [mTorr] (1.333 [Pa])

Flow rate of Kr gas: 170 [sccm]

Flow rate of methane (CH₄) gas: 30 [sccm]

First radio frequency wave: 60 [MHz], 200 [W]

Second radio frequency wave: 400 [kHz], 800 [W]

Processing time: 5 [seconds]

### Second Step

Pressure in Internal space: 10 [mTorr] (1.333 [Pa])

Flow rate of Ne gas: 50 [sccm]

Flow rate of oxygen (O₂) gas: 10 [sccm]

Flow rate of carbon monoxide (CO) gas: 140 [sccm]

First radio frequency wave: 60 [MHz], 200 [W]

Second radio frequency wave: 400 [kHz], 800 [W]

Processing time: 5 [seconds]

Number of executions of sequence: 30 times

In the first experiment, the magnetoresistance (MR) ratio of each of the plurality of fabricated experimental samples 1 and the plurality of fabricated comparative samples 1 was measured. As a result of the measurement, the average value of the MR ratios of the plurality of experimental samples 1 was 188.5%, and the average value of the MR ratios of the plurality of comparative samples 1 was 180.3%. The plurality of experimental samples 1 had a higher MR. ratio than the plurality of comparative samples 1 in which the etching was performed using a methane gas. According to the execution of the sequence which includes steps ST1 and ST2, it was confirmed that the deterioration of the magnetic characteristics of the magnetoresistance effect device was suppressed.

(Second Experiment)

In the second experiment, a plurality of experimental samples 2 were fabricated in the same manner as the plurality of experimental samples 1 described above. For comparison, a plurality of comparative samples 2 were fabricated in the same manner as the plurality of comparative samples 1 described above. Then, with respect to each of the plurality of experimental samples 2 and the plurality of comparative samples 2, a coercive force was determined from a magnetization curve created using a sample vibration type magnetometer. As a result of the measurement, the average value of the coercive forces Hc (average coercive force) of the plurality of experimental samples 2 was 1590 (Oe), and the average value of the coercive forces Hc (average coercive force) of the plurality of comparative samples 2 was 951 (Oe). That is, the experimental samples 2 had a higher average coercive force than the comparative samples 2. Accordingly, it was confirmed that the deterioration of the magnetic characteristics of the magnetoresistance effect device could be suppressed by using the plasma of the first gas and the plasma of the second gas, which do not include hydrogen, in the etching of the multilayer film ML.

(Third Experiment)

In the third experiment, the relationship between the number of executions of the sequence in overetching which is executed after main etching of the multilayer film and the coercive force was obtained. A plurality of experimental samples 3 and a plurality of comparative samples 3 were fabricated in the third experiment. In the fabrication of the plurality of experimental samples 3, the main etching of the multilayer film of the workpiece having the structure shown in FIG. 2 was performed under the same processing conditions as the processing conditions in the fabrication of the plurality of experimental samples 1 described above. In the fabrication of some experimental samples among the plurality of experimental samples 3, the overetching was not executed. In the overetching in the fabrication of other experimental samples 3 among the plurality of experimental samples 3, the sequence was executed 6 times, 12 times, or 18 times under the same processing conditions as the processing conditions in the fabrication of the plurality of experimental samples 1. In the fabrication of the plurality of comparative samples 3, the main etching of the multilayer film of the workpiece having the structure shown in FIG. 2 was performed under the same processing conditions as the processing conditions in the fabrication of the plurality of comparative samples 1 described above. In the fabrication of some comparative samples among the plurality of comparative samples 3, the overetching was not executed. In the overetching in the fabrication of other comparative samples 3 among the plurality of comparative samples 3, the sequence was executed 6 times, 12 times, or 18 times under the same processing conditions as the processing conditions in the fabrication of the plurality of comparative samples 1. The plasma processing apparatus having the structure shown in FIG. 3 was used in the fabrication of each of the plurality of experimental samples 3 and the plurality of comparative samples 3.

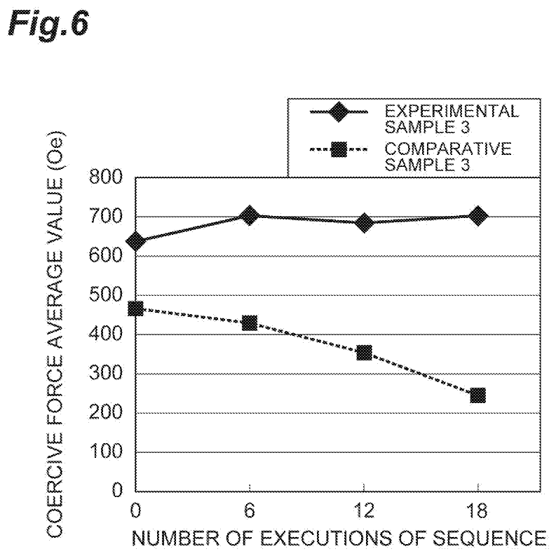

In the third experiment, with respect to each of the plurality of experimental samples 3 and the plurality of comparative samples 3, the coercive force was determined from the magnetization curve created using the sample vibration type magnetometer. Then, the relationship between the number of executions of the sequence in the overetching and the average value of the coercive force was obtained. The results of the third experiment are shown in FIG. 6. In the graph of FIG. 6, the horizontal axis represents the number of executions of the sequence in the overetching, and the vertical axis represents the average value of the coercive force. As shown in FIG. 6, the average value of the coercive forces of the plurality of experimental samples 3, that is, the samples fabricated by the execution of steps ST1 and ST2 was substantially constant regardless of the number of executions of the sequence in the overetching. The average value of the coercive forces of the plurality of comparative samples 3 fabricated using a methane gas decreased with an increase in the number of executions of the sequence in the overetching. From this result, according to the sequence which includes each of steps ST1 and ST2, it was confirmed that even if the overetching was executed in order to adjust the shape of the pillar formed from the multilayer film, it was possible to suppress the deterioration of the magnetic characteristics of the magnetoresistance effect device.

### REFERENCE SIGNS LIST

10: plasma processing apparatus

12: chamber body

12c: internal space

16: stage

18: lower electrode

20: electrostatic chuck

30: upper electrode

40: gas source group

50: exhaust device

62: first radio frequency power source

64: second radio frequency power source

W: workpiece

ML: multilayer film

L11: first magnetic layer

L12: tunnel barrier layer

L13: second magnetic layer

TL: magnetic tunnel junction layer

MK: mask

1. A method of etching a multilayer film of a workpiece, which is executed in manufacture of a magnetoresistance effect device,
wherein
the multilayer film has a magnetic tunnel junction layer, and the magnetic tunnel junction layer includes a first magnetic layer, a second magnetic layer, and a tunnel barrier layer provided between the first magnetic layer and the second magnetic layer, and
in the method of etching, a plasma processing apparatus including a chamber body is used, and the chamber body provides an internal space,
the method of etching comprising:
accommodating the workpiece in the internal space;
etching the multilayer film by plasma of a first gas generated in the internal space, the first gas including carbon and a rare gas, and not including hydrogen; and
further etching the multilayer film by plasma of a second gas generated in the internal space, the second gas including oxygen and a rare gas, and not including carbon and hydrogen.

2. The method of etching according to claim 1, wherein the first gas further includes oxygen.

3. The method of etching according to claim 2, wherein the first gas includes a carbon monoxide gas or a carbon dioxide gas.

4. The method of etching according to claim 1, wherein said etching the multilayer film by plasma of a first gas and said further etching the multilayer film by plasma of a second gas are alternately repeated.

5. The method of etching according to claim 1, further comprising:
generating plasma of a third gas in the internal space before accommodating the workpiece in the internal space,
wherein the third gas includes a gas containing carbon and a rare gas.

6. The method of etching according to claim 5, wherein the third gas includes a gas containing hydrocarbon, as the gas containing the carbon.

7. The method of etching according to claim 5, further comprising:
executing cleaning of a surface defining the internal space after the multilayer film is etched by executing said etching the multilayer film by plasma of a first gas and said further etching the multilayer film by plasma of a second gas.

8. The method of etching according to claim 7, further comprising:
transferring the workpiece out from the internal space after the multilayer film is etched and before said executing cleaning.

9. The method of etching according to claim 1, wherein each of the first magnetic layer and the second magnetic layer is a CoFeB layer, and the tunnel barrier layer is an MgO layer.
